(19) United States
(12) Patent Application Publication
(10) Pub. No.: US 2012/0298406 A1
(43) Pub. Date: Nov. 29, 2012

(54) REDUCED STRESS GULL WING SOLDER JOINTS FOR PRINTED WIRING BOARD CONNECTIONS

(75) Inventor: Wai Mon Ma, Austin, TX (US)

(73) Assignee: INTERNATIONAL BUSINESS MACHINES CORPORATION, New York, NY (US)

(21) Appl. No.: 13/113,259

(22) Filed: May 23, 2011

(51) Int. Cl. H05K 1/09; H05K 1/11; B23K 31/02

(52) U.S. Cl. 174/257; 228/180.22; 174/263

(57) ABSTRACT

Micro-vias that are conventionally used for vertical connections in wire or circuit boards may be used for an entirely different purpose; the micro-vias may be used in the creation of solder joints to initiate the controlled formation of voids that increase the reliability of the solder joints.

### TECHNICAL FIELD

The present invention relates to solder joints in printed wiring board integrated circuit technology, and particularly printed wiring boards using gull wing connectors.

### BACKGROUND OF RELATED ART

Microelectronic components are being continually miniaturized into area arrays. However, in these miniaturized area arrays, the reliability of solder joints is becoming increasingly significant. This is especially true with solder joints for gull wing connectors. Because of the cantilever structure of gull wing connectors, the solder joints are subject to increased structural stress.

Voids in the solder joint have been studied in the microelectronics art for their effect on solder junction reliability. Please refer to the article, “Effect of voids on the reliability of BSA/CPS solder joints”, Microelectronics Reliability, Vol. 43, 2003, pp. 2077-86.

### SUMMARY OF THE PRESENT INVENTION

I have found that intentionally created voids of controlled size can be used to increase junction reliability. I have further found that micro-vias, which are conventionally used for vertical connections in wire or circuit boards may be used for an entirely different purpose; the micro-vias may be used in the creation of solder joints to initiate the controlled formation of voids that, surprisingly, increase the reliability of the solder joints. Micro-vias are minute drilled horizontal holes in circuit boards that have a diameter of less than 6 mils, which are normally used to interconnect component contact.

In the present invention, the micro-vias are used beneath solder joints without any horizontal interconnectors for the sole purpose of creating voids. Accordingly, the present invention provides a method of forming a gull wing solder joint that comprises, first, forming a metallic mount pad on a printed wiring board (PWB). Then a central micro-via is formed in the mount pad. The micro-via is formed by any conventional method of forming micro-vias, such as microelectronic drilling mechanically or by laser. However, the drilled micro-vias are not conventionally vertically drilled through layers to provide interconnection routes. Herein, the drilled micro-vias form recesses in the mount pads that provide sites from which gases may expand during the thermal flowing of the solder to form the desirable voids in accordance with this invention.

At this point in the process, the solder paste is applied over the mount pad and associated micro-via, metallic gulf wing connector lead set on the solder paste, and the solder paste is thermally reflowed to thereby connect the connector lead to said pad to form a solder joint having a void co-extensive with said micro-via.

### BRIEF DESCRIPTION OF THE DRAWINGS

The present invention will be better understood and its numerous objects and advantages will become more apparent to those skilled in the art by reference to the following drawings, in conjunction with the accompanying specification, in which:

FIG. 1 is a diagrammatic view of an illustrative assembly showing an assembly stage when the mount pad is applied to the printed wiring board;

FIG. 2 illustrates the assembly of FIG. 1 at a next stage when the micro-via is drilled into the mount pad;

FIG. 3 illustrates the assembly of FIG. 2 at a next point when the thermal solder paste is applied;

FIG. 4 illustrates the assembly of FIG. 3 at a next stage after the solder paste is thermally reflowed to connect the gull wing connector; and

FIG. 5 is a diagrammatic illustration of a microscopic section of a final solder connection of a gull wing to the underlying pad mount.

### DETAILED DESCRIPTION OF THE PREFERRED EMBODIMENT

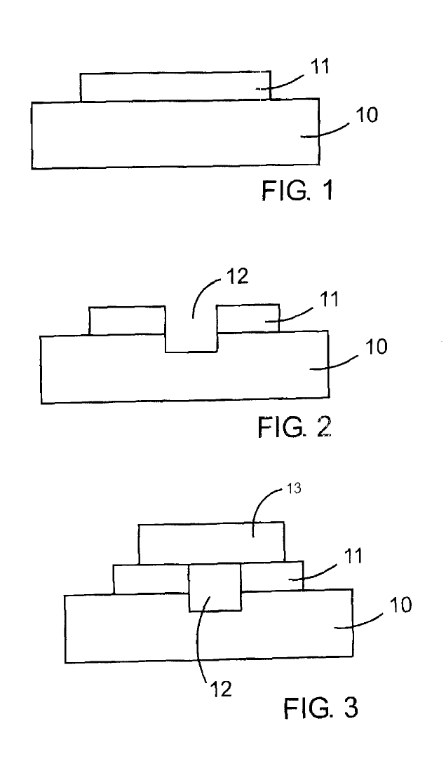

Now with reference to FIG. 1, a copper mount pad 11 is applied on the printed wiring board 10 by any conventional method.

Then, FIG. 2, using a mechanical or laser drill, micro-via 12 is cut in the middle of pad 11. The micro-via 11 is of such a size that the solder joint to be subsequently formed by thermal flow will have at least a 50% solder joint integrity. The micro-via 12 may be plated with copper or left unplated. A standard solder paste is applied over mount pad 11 to enclose micro-via cavity 12, FIG. 3.

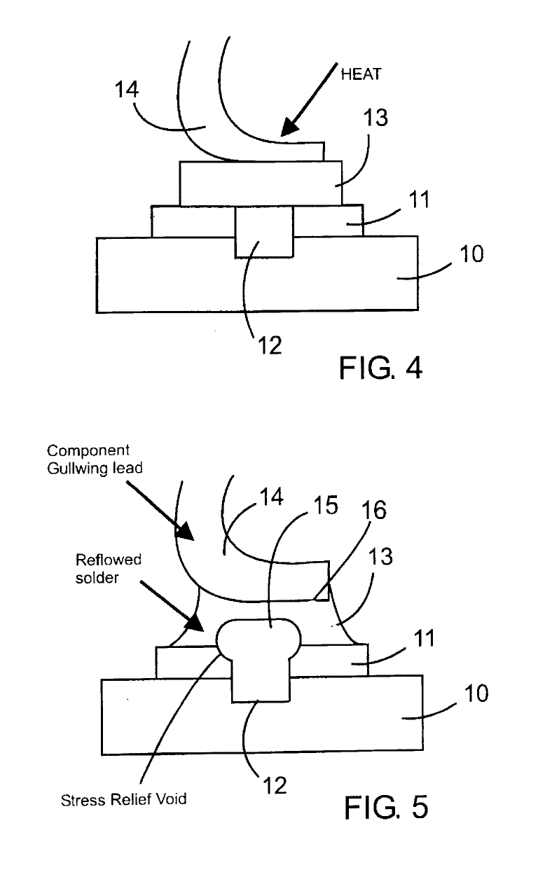

At this point, the gull wing connector 14 is placed against solder paste 13, and appropriate heat is applied to thermally flow solder paste 13, FIG. 4.

The resulting final structure is shown in FIG. 5. The solder has reflowed to form the solder joint 13 connecting gull wing 14 to pad mount 11. However, air and gases released during reflow and trapped have formed a solder joint stress relieving void 15 extending from micro-via 12. This void absorbs reflowed solder to expansion to some degree. Should any crack 16 form at the interface between the gull wing connector 14 and reflowed solder 13, the continuation of the cracking will be stopped by void 15.

### DETAILED DESCRIPTION OF THE PREFERRED EMBODIMENT

Now with reference to FIG. 1, a copper mount pad 11 is applied on the printed wiring board 10 by any conventional method.

Then, FIG. 2, using a mechanical or laser drill, micro-via 12 is cut in the middle of pad 11. The micro-via 11 is of such a size that the solder joint to be subsequently formed by thermal flow will have at least a 50% solder joint integrity. The micro-via 12 may be plated with copper or left unplated. A standard solder paste is applied over mount pad 11 to enclose micro-via cavity 12, FIG. 3.

At this point, the gull wing connector 14 is placed against solder paste 13, and appropriate heat is applied to thermally flow solder paste 13, FIG. 4.

The resulting final structure is shown in FIG. 5. The solder has reflowed to form the solder joint 13 connecting gull wing 14 to pad mount 11. However, air and gases released during reflow and trapped have formed a solder joint stress relieving void 15 extending from micro-via 12. This void absorbs reflowed solder to expansion to some degree. Should any crack 16 form at the interface between the gull wing connector 14 and reflowed solder 13, the continuation of the cracking will be stopped by void 15.

Although certain preferred embodiments have been shown and described, it will be understood that many changes and modifications may be made therein without departing from the scope and intent of the appended claims.

What is claimed is:

1. A method of forming a gull wing solder joint comprising:
forming a metallic mount pad on a printed wiring board (PWB);
forming a micro-via in said mount pad;
applying solder paste over said mount pad and micro-via;
applying a metallic gulf wing connector lead to the solder paste; and
thermally reflowing said solder paste to connect said connector lead to said pad to form a solder joint having a void co-extensive with said micro-via.

2. The method of claim 1, wherein said micro-via is extended through said mount pad partially into said PWB.

3. The method of claim 1, wherein said micro-via is formed by drilling into said mount pad.

4. The method of claim 3, wherein said micro-via is extended into said underlying PWB.

5. The method of claim 1, wherein said mount pad is a copper surface mount pad.

6. The method of claim 5, wherein said micro-via is plated with copper prior to applying said solder paste.

7. The method of claim 2, wherein said solder joint has at least 50% joint integrity with respect to the void.

8. The method of claim 1, wherein said micro-via is central in the mount pad.

9. A gulf wing solder joint formed by the method comprising:
forming a metallic mount pad on a printed wiring board (PWB);
forming a micro-via in said mount pad;
applying solder paste over said mount pad and micro-via;
applying a metallic gulf wing connector lead to the solder paste; and
thermally reflowing said solder paste to connect said connector lead to said pad to form a solder joint having a void co-extensive with said micro-via.

10. The solder joint of claim 9, wherein said micro-via is extended through said mount pad partially into said PWB.

11. The solder joint of claim 9, wherein said micro-via is formed by drilling through said mount pad.

12. The solder joint of claim 11 wherein said micro-via is extended partially into said underlying PWB.

13. The solder joint of claim 9 wherein said mount pad is a copper surface mount pad.

14. The solder joint of claim 13, wherein said micro-via is plated with copper prior to applying said solder paste.

15. The solder joint of claim 14, wherein said solder joint has at least 50% joint integrity with respect to the void.

16. The solder joint of claim 9, wherein said micro-via is central to the mount pad.
